(19) United States
(12) Patent Application Publication
(10) Pub. No.: US 2026/0293267 A1
(43) Pub. Date: Sep. 24, 2026

(54) SEMICONDUCTOR DEVICE AND METHOD FOR MANUFACTURING SEMICONDUCTOR DEVICE

(71) Applicants: FUJI ELECTRIC CO., LTD., Kanagawa (JP); DENSO CORPORATION, Aichi (JP)

(72) Inventor: Naoyuki OHSE, Matsumoto-city (JP)

(21) Appl. No.: 19/545,022

(22) Filed: Feb. 20, 2026

(30) Foreign Application Priority Data
Mar. 19, 2025 (JP) 2025-044814

(51) Int. Cl. H10D 64/62; H10D 62/40; H10D 62/832; H10D 64/01

(52) U.S. Cl. CPC H10D 64/62; H10D 62/40; H10D 62/8325; H10D 64/0112; H10D 64/0115

(57) ABSTRACT

There is provided a semiconductor device including: a SiC substrate which has an upper surface and a lower surface; an element structure which is formed on the upper surface of the SiC substrate; a metal silicide portion which is formed at a part of the lower surface of the SiC substrate; and a lower surface electrode which is in contact with the metal silicide portion and with an exposed region of the lower surface which is not covered by the metal silicide portion, in which at least a part of the exposed region has a crystal structure different from that of a contact region of the SiC substrate which is in contact with the metal silicide portion.

The contents of the following patent application(s) are incorporated herein by reference: NO. 2025-044814 filed in JP on Mar. 19, 2025.

### BACKGROUND

### 1. TECHNICAL FIELD

The present invention relates to a semiconductor device and a method for manufacturing a semiconductor device.

### 2. RELATED ART

In the related art, a silicon carbide semiconductor device in which a first region having a silicide layer between the silicon carbide semiconductor substrate and the back electrode, and a second region where the silicon carbide semiconductor substrate and the back electrode directly contact each other, are alternately arranged in stripes, is known (for example, refer to Patent Document 1). In addition, a semiconductor device including a modified layer between a SiC semiconductor substrate and an electrode is known (for example, Patent Document 2).

Patent Document 1: Japanese Patent Application Publication No. 2017-63145

Patent Document 2: WO 2019/189242

### BRIEF DESCRIPTION OF THE DRAWINGS

FIG. 1 is a diagram showing an example of a configuration of a semiconductor device 100 according to one embodiment of the present invention.

FIG. 2A is an enlarged view of a structure 1 in FIG. 1.

FIG. 2B is an enlarged view of a structure 2 in FIG. 1.

FIG. 2C is an enlarged view of a region A in FIG. 1.

FIG. 3 is a diagram showing an example of a manufacturing step of the semiconductor device 100 according to an embodiment.

FIG. 4A shows a cross-sectional view of the semiconductor device 100 in an upper surface device structure forming step S1000.

FIG. 4B shows a cross-sectional view of the semiconductor device 100 in a wafer thinning processing step S1002.

FIG. 4C shows a cross-sectional view of the semiconductor device 100 in an ohmic metal deposition step S1004.

FIG. 4D shows a cross-sectional view of the semiconductor device 100 in a first laser annealing step S1006.

FIG. 4E shows a cross-sectional view of the semiconductor device 100 in a second laser annealing step S1008.

FIG. 4F shows a cross-sectional view of the semiconductor device 100 in a surface etching step S1010.

FIG. 4G shows a cross-sectional view of the semiconductor device 100 in a lower surface electrode forming step S1012.

FIG. 5 is a diagram showing an example of a manufacturing step of a semiconductor device 200 according to a comparative example.

FIG. 6A shows a cross-sectional view of the semiconductor device 200 in an upper surface device structure forming step S1000.

FIG. 6B shows a cross-sectional view of the semiconductor device 200 in a wafer thinning processing step S1002.

FIG. 6C shows a cross-sectional view of the semiconductor device 200 in an ohmic metal deposition step S1004.

FIG. 6D shows a cross-sectional view of the semiconductor device 200 in a laser annealing step S1006.

FIG. 6E shows a cross-sectional view of the semiconductor device 200 in a surface etching step S1008.

FIG. 6F shows a cross-sectional view of the semiconductor device 200 in a lower surface electrode forming step S1010.

FIG. 7 shows an example of a schematic diagram of a lower surface 23 of a SiC substrate 11.

FIG. 8 shows another example of the schematic diagram of the lower surface 23 of the SiC substrate 11.

### DESCRIPTION OF EXEMPLARY EMBODIMENTS

The present invention will be described below through embodiments of the invention, but the following embodiments do not limit the invention according to the claims. Further, not all of combinations of features described in the embodiments are essential to the solving means of the invention. In the present specification, the same parts in each figure are denoted by the same signs and numerals, and the descriptions thereof may be omitted. In addition, for convenience of description, some configurations may not be illustrated.

In the present specification, one side in a direction parallel to a depth direction of a semiconductor substrate or a semiconductor device is referred to as an "upper" side and another side is referred to as a "lower" side. One surface of two principal surfaces of a substrate, a device, a layer, or another member is referred to as an upper surface, and another surface is referred to as a lower surface. "Upper" and "lower" directions are not limited to a direction of gravity, or a direction in which a semiconductor device is mounted.

In the present specification, technical matters may be described using an orthogonal coordinate system of an X axis, a Y axis, and a Z axis. The orthogonal coordinate system merely specifies relative positions of components, and does not limit a particular direction. For example, a Z axis direction is not limited to showing a height direction with respect to the ground. It should be noted that a +Z axis direction and a -Z axis direction are directions opposite to each other. When the Z axis direction is described without describing the signs, it means that the direction is parallel to a +Z axis and a -Z axis.

In the present specification, orthogonal axes parallel to the upper surface and the lower surface of the semiconductor substrate or the semiconductor device are referred to as the X axis and the Y axis. In addition, an axis perpendicular to the upper surface and the lower surface is referred to as the Z axis. In the present specification, the Z axis direction may be referred to as a depth direction.

When a term such as “same” or “equal” is used herein, it may encompass a case where an error due to a variation in manufacturing or the like is included. The error is, for example, within 10%.

In the present specification, a conductivity type of a doping region doped with impurities is described as a P type or an N type. In the present specification, the impurities may particularly mean either donors of the N type or acceptors of the P type and may be described as dopants. In the present specification, doping means introducing the donor or the acceptor into the semiconductor substrate and turning it into a semiconductor presenting a conductivity type of the N type, or a semiconductor presenting a conductivity type of the P type.

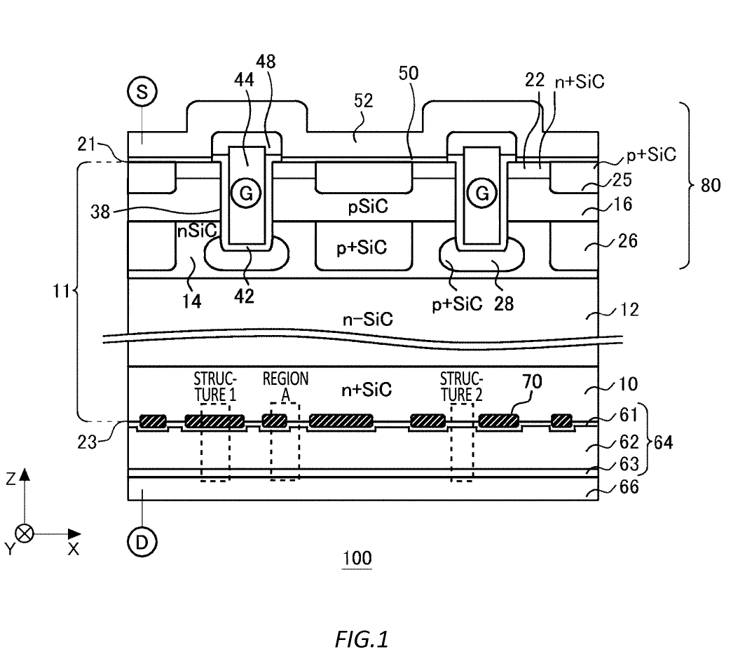

FIG. 1 is a diagram showing an example of a configuration of a semiconductor device 100 according to one embodiment of the present invention. The semiconductor device 100 of the present example is a silicon carbide semiconductor device. The semiconductor device 100 may be a vertical device in which a main current flows between an upper surface and a lower surface of the semiconductor device 100. The semiconductor device 100 of the present example is a vertical MOSFET (Metal Oxide Semiconductor Field Effect Transistor). Note that the semiconductor device 100 is not limited to this. The semiconductor device 100 may be a diode.

FIG. 1 is a cross-sectional view showing a part of the semiconductor device 100 taken along an XZ plane. In the present specification, a positive direction of the Z axis direction refers to the "upper" side, and a negative direction of the Z axis direction refers to the "lower" side. The semiconductor device 100 of the present example includes a silicon carbide substrate layer 10, a silicon carbide layer 12, an upper surface electrode 50, an upper surface electrode pad 52, a lower surface electrode 64, and a lower surface electrode pad 66.

A crystal structure of the silicon carbide substrate layer 10 may be a 4H-SiC crystal structure. The silicon carbide substrate layer 10 may be a so-called m-plane silicon carbide substrate. An m-axis direction of the silicon carbide substrate layer 10 may be parallel to the Z axis direction. The silicon carbide substrate layer 10 may also be a so-called Si-plane silicon carbide substrate. A Si-axis direction of the silicon carbide substrate layer 10 may be parallel to the Z axis direction. The silicon carbide substrate layer 10 may be a so-called C-plane silicon carbide substrate. A C-axis direction of the silicon carbide substrate layer 10 may be parallel to the Z axis direction. The silicon carbide substrate layer 10 may be a so-called a-plane silicon carbide substrate. An a-axis direction of the silicon carbide substrate layer 10 may be parallel to the Z axis direction. In addition, the silicon carbide substrate layer 10 may have a threading dislocation density of less than 1 × 10⁷ cm⁻². The silicon carbide substrate layer 10 of the present example is a substrate of an n+ type.

The silicon carbide layer 12 is a silicon carbide layer of an n- type which has an impurity concentration lower than that of the silicon carbide substrate layer 10. The silicon carbide layer 12 is a drift layer of an n type with a low concentration. The silicon carbide layer 12 is provided at an upper surface of the silicon carbide substrate layer 10. The silicon carbide layer 12 may be deposited by the epitaxial growth. On the opposite side of the silicon carbide layer 12 from a silicon carbide substrate layer 10 side, a high concentration region 14 is formed. The high concentration region 14 is a silicon carbide layer of the n type which has an impurity concentration lower than that of the silicon carbide substrate layer 10 and has an impurity concentration higher than that of the silicon carbide layer 12. The high concentration region 14 of the present example is a drift layer of the n type with a high concentration. The high concentration region 14 may be deposited by the epitaxial growth, or may be formed by doping by ion implantation. On the opposite side of the high concentration region 14 from a silicon carbide layer 12 side, a base layer 16 is formed. The base layer 16 of the present example is of a p type. The base layer 16 may be deposited by the epitaxial growth, or may be formed by doping by ion implantation.

In the present example, the silicon carbide substrate layer 10, the silicon carbide layer 12, the high concentration region 14, and the base layer 16 are collectively referred to as a SiC substrate 11. When another region is provided between the base layer 16 and the upper surface electrode 50, the other region may also be included in the SiC substrate 11. In other words, the SiC substrate 11 refers to the semiconductor substrate and the semiconductor layer between the upper surface electrode 50 and the lower surface electrode 64. The semiconductor device 100 includes the SiC substrate 11. The SiC substrate 11 has an upper surface 21 and a lower surface 23. The upper surface electrode 50 is provided in contact with the upper surface 21 of the SiC substrate 11, and functions as a source electrode. The lower surface electrode 64 is provided in contact with the lower surface 23 of the SiC substrate 11, and functions as a drain electrode.

A trench structure is formed at the upper surface 21 of the SiC substrate 11. Specifically, a trench 38 is formed from the upper surface 21 toward the inside of the SiC substrate 11. The trench 38 penetrates the base layer 16 from the upper surface (an upper surface 21 side of the SiC substrate 11) on the opposite side of the base layer 16 from the silicon carbide substrate layer 10 side, and reaches the high concentration region 14. A gate dielectric film 42 is formed, along an inner wall of the trench 38, on a bottom portion and a side wall of the trench 38. The gate dielectric film 42 may be a silicon dioxide layer, or may be formed by high temperature oxidation (HTO). Further, a gate electrode 44 is formed inside the gate dielectric film 42 in the trench 38. The gate electrode 44 is, for example, formed of polysilicon. By the gate dielectric film 42, the gate electrode 44 is insulated from the high concentration region 14 and the base layer 16. A part of the gate electrode 44 may protrude toward an upper surface electrode pad 52 side from above the trench 38. In addition, an interlayer dielectric film 48 may be formed on the gate electrode 44. The interlayer dielectric film 48 insulates the gate electrode 44 and the upper surface electrode pad 52.

A source region 22 and a contact region 25 are selectively provided, between the base layer 16 and the upper surface 21 of the SiC substrate 11. The source region 22 and the contact region 25 may be in contact with the upper surface electrode 50. In addition, the source region 22 may be in contact with the trench 38. In the present example, the source region 22 is of the n+ type, and the contact region 25 is of a p+ type. The source region 22 and the contact region 25 may be formed by doping.

A first base region 26 and a second base region 28 are selectively provided in the high concentration region 14 of the present example. A lower end portion of the first base region 26 is positioned closer to a lower surface electrode 64 side than the bottom portion of the trench 38. A lower end portion of the second base region 28 is positioned closer to the lower surface electrode 64 side than the bottom portion of the trench 38. The second base region 28 is formed at a position facing the bottom portion of the trench 38 in the depth direction (Z axis direction). A width of the second base region 28 in an X axis direction may be greater than a width of the trench 38 in the X axis direction. The bottom portion of the trench 38 may reach the second base region 28, or may be positioned in the high concentration region 14 sandwiched between the base layer 16 and the second base region 28 so as not to contact the second base region 28. In the present example, the bottom portion of the trench 38 reaches the second base region 28. In the present example, the first base region 26 and the second base region 28 are of the p+ type. In the first base region 26 and the second base region 28, for example, an aluminum element is doped.

By supplying a predetermined positive potential to the gate electrode 44, a charge inversion region (that is, a channel) is formed in the base layer 16. When a predetermined potential difference is formed between the upper surface electrode 50 (upper surface electrode pad 52) and the lower surface electrode 64 (lower surface electrode pad 66), the electron current flows from the upper surface electrode 50 to the lower surface electrode 64 through the channel.

In the present specification, a structure formed on the upper surface 21 of the SiC substrate 11 is referred to as an element structure 80. In a case of the present example, the trench 38, the high concentration region 14, the base layer 16, the source region 22, the contact region 25, and the upper surface electrode 50 are included in the element structure 80. That is, between two principal surfaces of the SiC substrate 11, the surface on which the element structure 80 is formed is the upper surface 21. When the semiconductor device 100 is not a MOSFET of a trench type, the element structure 80 may refer, for example, to a gate structure, or may refer to an anode region in the diode.

The semiconductor device 100 of the present example includes a metal silicide portion 70 formed at a part of the lower surface 23 of the SiC substrate 11. The metal silicide portion 70 of the present example is not formed at a part of the lower surface 23 of the SiC substrate 11. In FIG. 1 and the subsequent figures, the metal silicide portion 70 is hatched. The metal silicide portion 70 is formed between the SiC substrate 11 and the lower surface electrode 64. In FIG. 1, a portion in which the metal silicide portion 70 is formed is referred to as a "structure 1". The structure 1 of the present example has a stacked structure of the SiC substrate 11, the metal silicide portion 70, and the lower surface electrode 64, in the depth direction. In addition, a portion in which the metal silicide portion 70 is not formed is referred to as a "structure 2". The structure 2 of the present example has a stacked structure of the SiC substrate 11 and the lower surface electrode 64, in the depth direction. In addition, a region including both of the structure 1 and the structure 2 is referred to as a "region A".

The lower surface electrode 64 is in contact with the metal silicide portion 70 and with a region (an exposed region described below) of the lower surface 23 which is not covered by the metal silicide portion 70. The lower surface electrode 64 may be in contact with the entire surface of the lower surface 23 of the SiC substrate 11. The lower surface electrode 64 may have a stacked structure. The lower surface electrode 64 of the present example has a stacked structure of a Ti layer 61, a Ni layer 62, and an Au layer 63 from a lower surface 23 side of the SiC substrate 11.

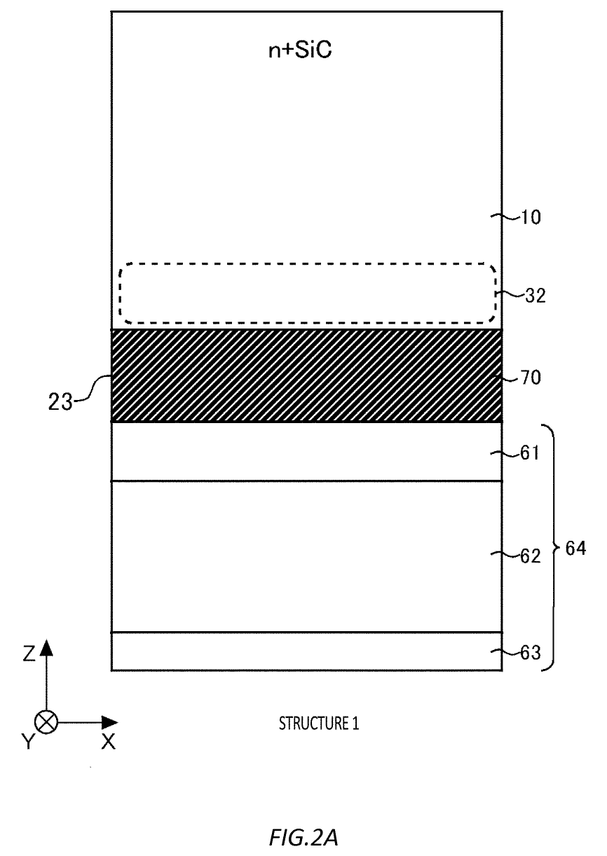

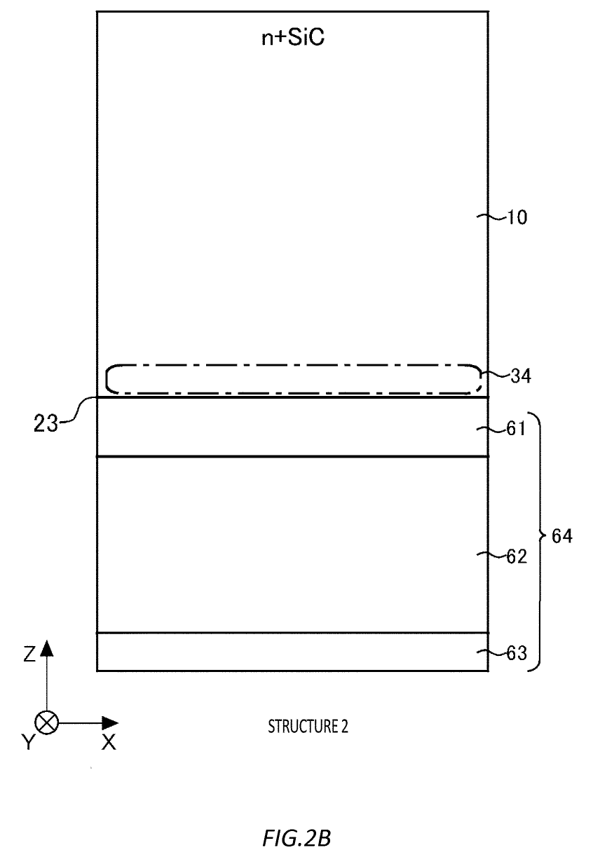

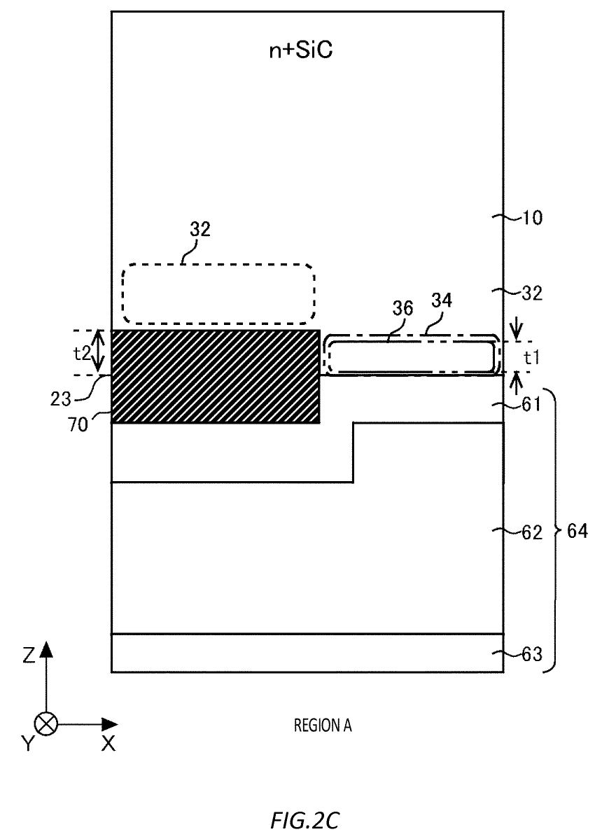

FIG. 2A is an enlarged view of the structure 1 in FIG. 1. As described above, in the structure 1, the metal silicide portion 70 is formed between the SiC substrate 11 and the lower surface electrode 64. The metal silicide portion 70 of the present example is nickel (Ni) silicide. Note that the metal silicide portion 70 may be NiMo (molybdenum) silicide, or may be NiTi silicide. In addition, a region of the SiC substrate 11 which is in contact with the metal silicide portion 70 is set as a contact region 32. The contact region 32 of the present example is a region of the silicon carbide substrate layer 10 which is in contact with the metal silicide portion 70. A thickness of the contact region 32 in the depth direction may be 100 nm or more and 1 μm or less from an interface in contact with the metal silicide portion 70. In addition, a range of the contact region 32 in an XY plane may be a range overlapping the metal silicide portion 70. The crystal structure of the contact region 32 may include the 4H-SiC crystal structure. The crystal structure of the contact region 32 may be the same as the crystal structure of the silicon carbide substrate layer 10. The crystal structure of the contact region 32 may not include a 3C-SiC crystal structure.

A low resistance ohmic contact can be obtained at a contact interface between 4H-SiC and Ni silicide. Therefore, the silicon carbide substrate layer 10 having the 4H-SiC crystal structure and the metal silicide portion 70 which is Ni silicide form the low resistance ohmic contact. That is, the structure 1 is a contact interface that is electrically excellent.

However, there is a layer including carbon precipitated due to silicidation between the silicon carbide substrate layer 10 and the metal silicide portion 70, inside the metal silicide portion 70, or between the metal silicide portion 70 and the lower surface electrode 64, and thus there is a risk of delamination. Further, when high temperature processing is performed in a state in which Ni silicide is in contact with the Ti layer 61 of the lower surface electrode 64, Ni in Ni silicide diffuses into the Ti layer 61, and a void is formed in Ni silicide, and thus there is a risk of delamination.

FIG. 2B is an enlarged view of the structure 2 in FIG. 1. As described above, in the structure 2, the metal silicide portion 70 is not formed, and the lower surface electrode 64 is in direct contact with the lower surface 23 of the SiC substrate 11.

Here, a region of the lower surface 23 which is not covered with the metal silicide portion 70 is set as an exposed region 34. That is, in the structure 2, the exposed region 34 of the SiC substrate 11 is in contact with the Ti layer 61 of the lower surface electrode 64. The thickness of the exposed region 34 in the depth direction may be 0 nm or more and 200 nm or less from the lower surface 23 of the SiC substrate 11.

In the present example, at least a part of the exposed region 34 has a crystal structure different from that of the contact region 32. As an example, the crystal structure of the exposed region 34 includes the 3C-SiC crystal structure. At least a part of the exposed region 34 may have a crystal structure different from that of the silicon carbide substrate layer 10, or may have a crystal structure different from that of the SiC substrate 11. The crystal structure of the SiC substrate 11 may refer to a crystal structure that occupies the largest volume, in the SiC substrate 11. The crystal structure of the SiC substrate 11 may be the 4H-SiC crystal structure. Note that the exposed region 34 may include amorphous SiC, may include microcrystalline SiC, or may include 4H-SiC that is not a single crystal, in addition to 3C-SiC. The crystal structure can be identified, for example, by cross-sectional analysis using the TEM or the like. The exposed region 34 may have the 3C-SiC crystal structure at an interface with the Ti layer 61. The 3C-SiC crystal structure may occupy the greatest area at the interface. Over the entirety of the interface, the exposed region 34 may have the 3C-SiC crystal structure.

The metal silicide portion 70 is not formed in the structure 2, and thus carbon described above is not precipitated, and the void is not formed, and thus there is a reduced risk of delamination. In addition, a contact between 3C-SiC and Ti forms an ohmic contact. Note that ohmic resistance of 3C-SiC and Ti is higher than ohmic resistance of 4H-SiC and Ni silicide.

As shown in FIG. 1, the semiconductor device 100 of the present example has both of the structure 1 and the structure 2. That is, contacts of the lower surface 23 are formed in both of the structure 1 which has low resistance but has a risk of delamination, and the structure 2 which has a reduced risk of delamination but has comparatively high resistance. Therefore, disadvantages cancel out each other, and it is possible to form a contact with low resistance and with high contact reliability. It should be noted that between the silicon carbide substrate layer 10 of 3C-SiC and the Ti layer 61, SiC of another crystal structure such as amorphous SiC which is thin enough to form the ohmic contact, may be formed.

FIG. 2C is an enlarged view of the region A in FIG. 1. The region A is a region including the structure 1, the structure 2, and a boundary therebetween. As a 3C-SiC region 36, a region of the exposed region 34 which has only the 3C-SiC crystal structure is set. The exposed region 34 may have only the 3C-SiC region 36, or may further have a region of another crystal structure. The thickness of the 3C-SiC region 36 in the depth direction is set as t1. For the thickness t1, a maximum thickness of the 3C-SiC region 36 may be used. An end portion of the 3C-SiC region 36 on a positive side of the Z axis may be a boundary between the 3C-SiC crystal structure and another crystal structure.

A part of the metal silicide portion 70 is provided inside the SiC substrate 11 (on the positive side of the Z axis) relative to the lower surface 23 of the SiC substrate 11, and another part is provided outside (on a negative Z axis side) relative to the lower surface 23. A surface of the surfaces of the SiC substrate 11 which is positioned outermost (on the negative side of the Z axis) may be set as the lower surface 23. The thickness of a part of the metal silicide portion 70 which is inside the SiC substrate 11 is set as t2. For the thickness t2, a maximum thickness of the part of the metal silicide portion 70 which is inside the SiC substrate 11, may be used. The thickness t1 may be smaller than the thickness t2. The 3C-SiC crystal structure is formed via a crushed layer which is formed at the lower surface 23 in a manufacturing step described below. On the other hand, when the crushed layer remains between the metal silicide portion 70 and the silicon carbide substrate layer 10, there is a possibility of delamination, and thus the metal silicide portion 70 is formed up to the positive side of the Z axis relative to the crushed layer. As a result, the configuration shown in FIG. 2C is obtained.

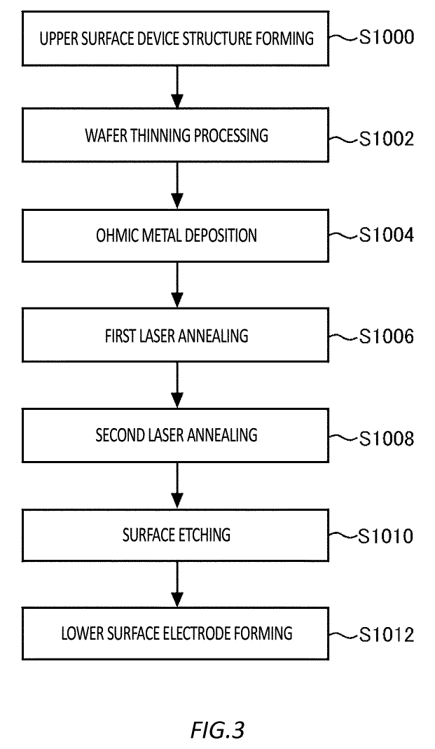

FIG. 3 is a diagram showing an example of a manufacturing step of the semiconductor device 100 according to an embodiment. The manufacturing steps of the present example include an upper surface device structure forming step S1000, a wafer thinning processing step S1002, an ohmic metal deposition step S1004, a first laser annealing step S1006, a second laser annealing step S1008, a surface etching step S1010, and a lower surface electrode forming step S1012.

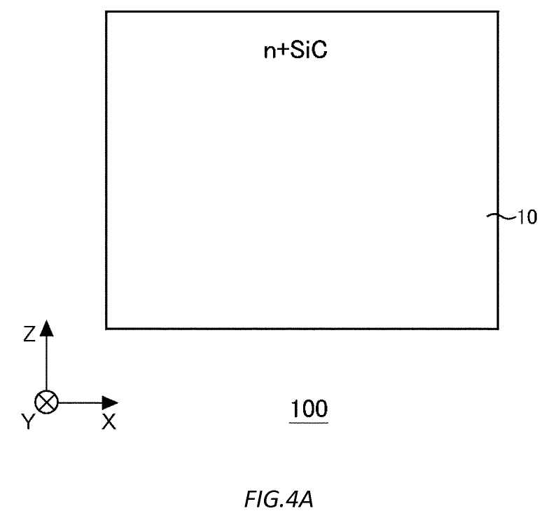

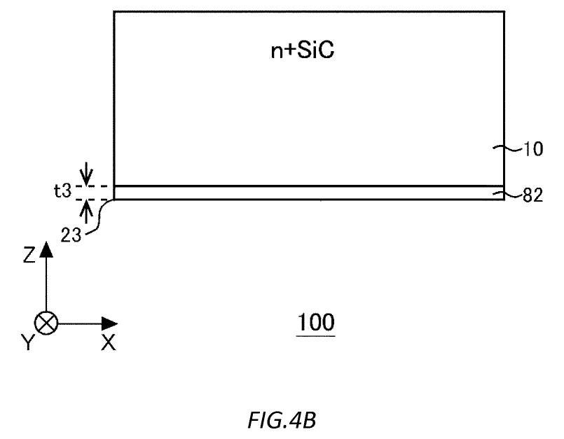

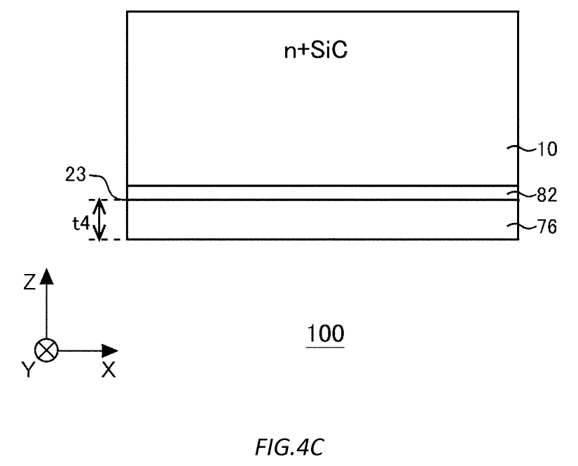

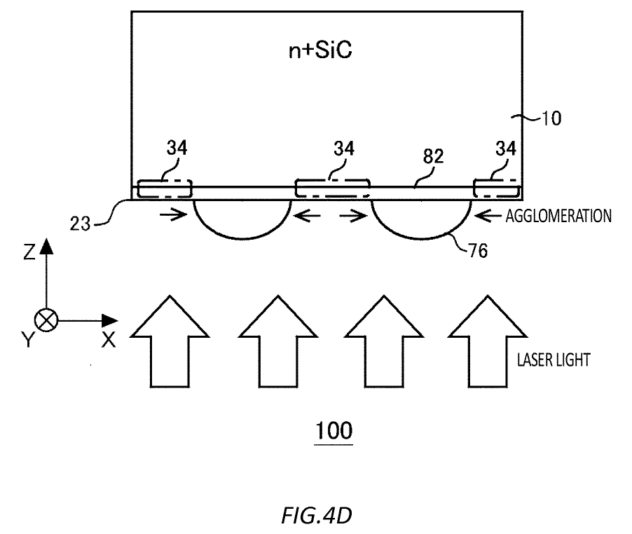

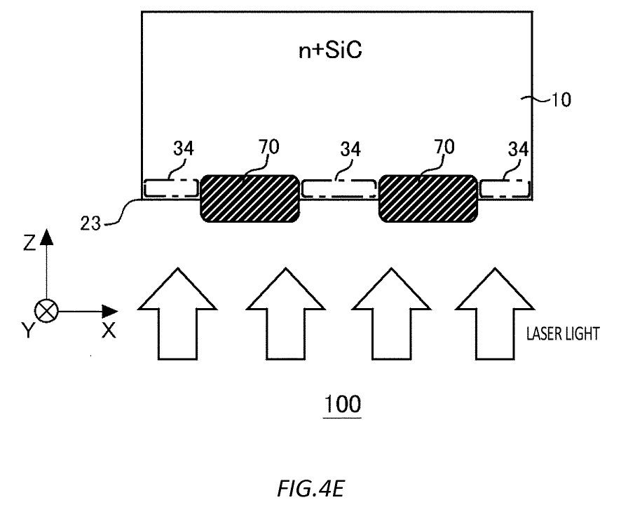

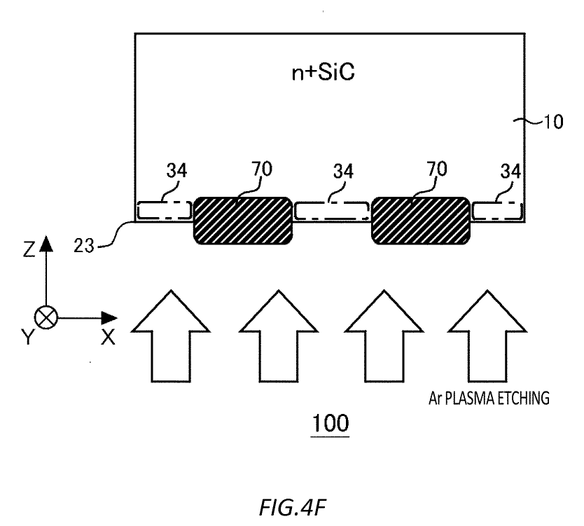

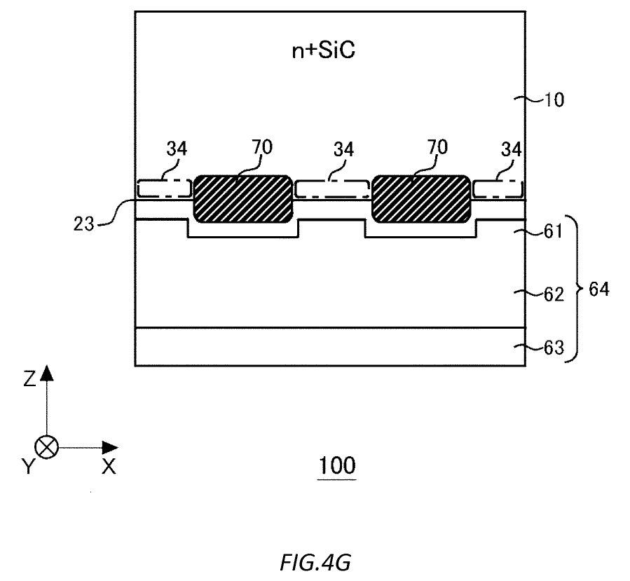

FIGS. 4A to 4G respectively show cross-sectional views of the semiconductor device 100 at manufacturing steps shown in FIG. 3. Note that in FIGS. 4A to 4G, the configuration on the upper surface 21 side from the silicon carbide substrate layer 10 is omitted. FIG. 4A shows a cross-sectional view of the semiconductor device 100 in the upper surface device structure forming step S1000. In the upper surface device structure forming step s1000, for example, the element structure 80 described in FIG. 1 is formed on the upper surface 21 side. Note that in FIG. 4A, the element structure 80 is also omitted.

FIG. 4B shows a cross-sectional view of the semiconductor device 100 in the wafer thinning processing step S1002. The wafer thinning processing step S1002 is a back grinding step of adjusting the thickness of the SiC substrate 11 by grinding the lower surface 23 of the SiC substrate 11. At this time, a crushed layer 82 is formed at the lower surface 23 of the SiC substrate 11. The crushed layer 82 refers to a layer in which the crystal structure of the silicon carbide substrate layer 10 is disordered by the back grinding. The crushed layer 82 may be a region including amorphous SiC, or may be a region including microcrystalline SiC. When the crystal structure of the silicon carbide substrate layer 10 is a single crystal of 4H-SiC, the crushed layer 82 may be a region which is not the single crystal of 4H-SiC.

Typically, the crushed layer 82 is removed from the lower surface 23; however, in the present example, the crushed layer 82 which is thin remains at the lower surface 23. The crushed layer 82 which remains becomes a layer of 3C-SiC in a step described below. A thickness t3 of the crushed layer 82 may be thinner than the thickness t2 (refer to FIG. 2C) of a part of the metal silicide portion 70 which is inside the SiC substrate 11. The thickness t3 of the crushed layer 82 may be 10 nm or more and 300 nm or less. In addition, in order to achieve the thickness described above, the lower surface 23 may be ground with a grinding tool having a grain size (also referred to as grit) of #1000 or more and #10000 or less for roughness of the surface that is ground.

FIG. 4C shows a cross-sectional view of the semiconductor device 100 in the ohmic metal deposition step S1004. In the ohmic metal deposition step S1004, an ohmic metal 76 is deposited at least at a part of the lower surface 23 of the SiC substrate 11. The ohmic metal 76 may be a Ni-based metal film. The ohmic metal 76 is, for example, Ni, NiMo, NiTi, or the like. The ohmic metal 76 is deposited by sputtering as an example. The ohmic metal 76 may be deposited over the entire surface of the lower surface 23, or may be partially patterned and deposited as described below. A film thickness t4 of the ohmic metal 76 that is deposited may be 50 nm or more and 300 nm or less.

FIG. 4D shows a cross-sectional view of the semiconductor device 100 in the first laser annealing step S1006. FIG. 4E shows a cross-sectional view of the semiconductor device 100 in the second laser annealing step S1008. In the first laser annealing step S1006 and the second laser annealing step S1008, laser annealing is performed on the ohmic metal 76 to cause agglomeration and silicidation, and a metal silicide portion is formed.

In the first laser annealing step S1006, the laser annealing is performed on the ohmic metal 76 to melt and agglomerate the ohmic metal 76 by heat. In this manner, a part of the lower surface 23 of the SiC substrate 11 is exposed, and the exposed region 34 is formed. Note that at this step, the exposed region 34 does not include the 3C-SiC crystal structure, and includes the crushed layer 82.

In the second laser annealing step S1008, by performing the laser annealing on at least a part of the lower surface 23 of the SiC substrate 11, the 3C-SiC crystal structure is formed. Specifically, the laser annealing is performed on the agglomerated ohmic metal 76 and the exposed region 34. The agglomerated ohmic metal 76 is silicided to form the metal silicide portion 70. In the exposed region 34, laser light is directly radiated onto the SiC substrate 11, and the crushed layer 82 changes to have the 3C-SiC crystal structure. In this manner, the exposed region 34 includes the 3C-SiC crystal structure. In the second laser annealing step S1008, the laser light is directly radiated onto at least a part of the lower surface 23 of the SiC substrate 11. The expression of directly means that no metal film or the like is deposited at a surface of the lower surface 23. In a case of the present example, the 3C-SiC crystal structure is not formed at a part of the SiC substrate 11 which is covered with the ohmic metal 76 or the metal silicide portion 70.

The metal silicide portion 70 is also formed inside the SiC substrate 11. At this time, when the crushed layer 82 remains between the SiC substrate 11 and the metal silicide portion 70, there is a possibility of delamination starting from the location. Therefore, the metal silicide portion 70 may be formed deeper than the crushed layer 82.

On the other hand, the 4H-SiC crystal structure is comparatively stable, and even when the laser light is radiated, there is almost no change in the 3C-SiC crystal structure. By the laser annealing, the crushed layer 82 changes to have the 3C-SiC crystal structure, and the crystal structure of the silicon carbide substrate layer 10 on a side above the crushed layer 82 is maintained. Therefore, at the lower surface 23 of the SiC substrate 11, the thickness t1 of the 3C-SiC region 36 (refer to FIG. 2C) which is a region having only the 3C-SiC crystal structure, becomes at most equal to the thickness t3 of the crushed layer 82. Therefore, when the metal silicide portion 70 is formed deeper than the crushed layer 82, the 3C-SiC region 36 is formed only up to a position shallower than the metal silicide portion 70.

A higher laser output is required for the silicidation of the silicon carbide substrate layer 10 than for the agglomeration of the ohmic metal 76. Therefore, a laser output in the second laser annealing step S1008 may be higher than a laser output in the first laser annealing step S1006.

The laser output in the first laser annealing step S1006 may be 2.0 J/cm² or more and 3.6 J/cm² or less. A laser wavelength of the first laser annealing step S1006 may be 355 nm. Radiation processing is performed in an inert gas atmosphere of nitrogen or the like, and an oxygen concentration may be 100 ppm or less.

The laser output in the second laser annealing step S1008 may be 3.4 J/cm² or more and 4.0 J/cm² or less. A laser wavelength of the second laser annealing step S1008 may be 355 nm. Radiation processing is performed in an inert gas atmosphere of nitrogen or the like, and an oxygen concentration may be 100 ppm or less.

Note that the first laser annealing step S1006 and the second laser annealing step S1008 may be single combined laser annealing step. That is, the conditions such as the laser output described above may all be the same in the first laser annealing step S1006 and in the second laser annealing step S1008.

FIG. 4F shows a cross-sectional view of the semiconductor device 100 in the surface etching step S1010. Carbon is precipitated at a front layer when the metal silicide portion 70 is formed in the second laser annealing step S1008. In addition, a microcrystalline layer or a carbon layer is also formed at a front layer of the exposed region 34 at which the 3C-SiC crystal structure is formed. In the surface etching step S1010, Ar plasma etching is performed on the lower surface 23, thereby removing precipitated carbon and the like that may cause delamination.

FIG. 4G shows a cross-sectional view of the semiconductor device 100 in the lower surface electrode forming step S1012. In the lower surface electrode forming step S1012, the lower surface electrode 64 is formed to be in contact with both of the metal silicide portion 70 and 3C-SiC. In other words, a part of the lower surface electrode 64 is in contact with the metal silicide portion 70, and another part is in contact with the SiC substrate 11 in the exposed region 34.

The lower surface electrode 64 may have a stacked structure. At this time, in order to form the ohmic contact with 3C-SiC, a side of the stacked structure closest to the SiC substrate 11 may be formed of Ti. The lower surface electrode 64 of the present example has the Ti layer 61, the Ni layer 62, and the Au layer 63 from a SiC substrate 11 side, in order.

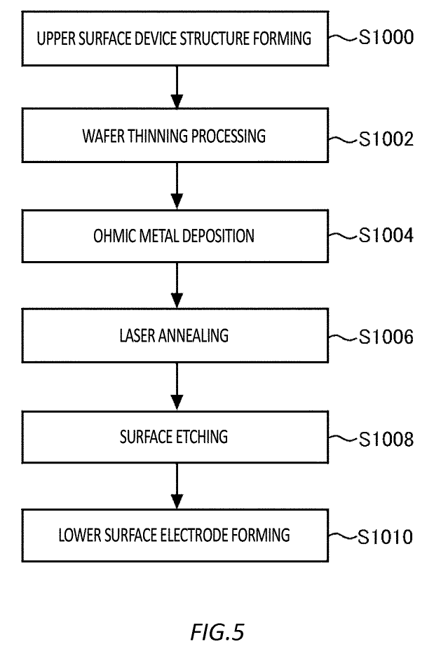

FIG. 5 is a diagram showing a manufacturing step of a semiconductor device 200 according to a comparative example. The manufacturing steps of the present example include the upper surface device structure forming step S1000, the wafer thinning processing step S1002, the ohmic metal deposition step S1004, a laser annealing step S1006, a surface etching step S1008, and a lower surface electrode forming step S1010.

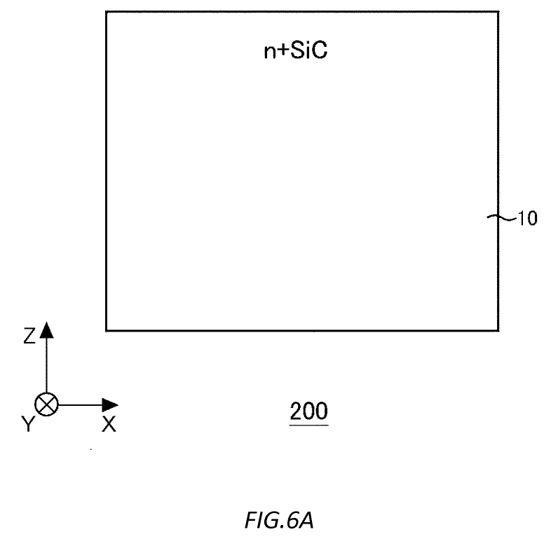

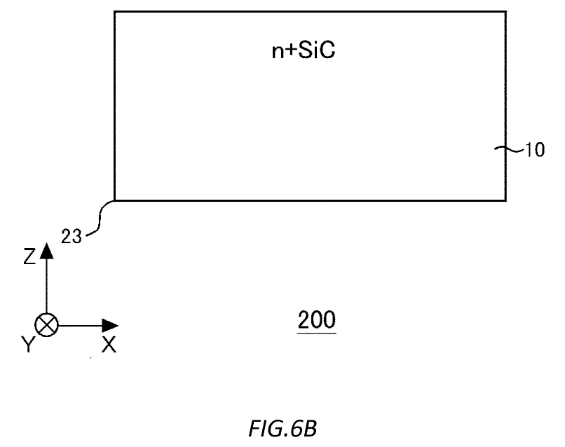

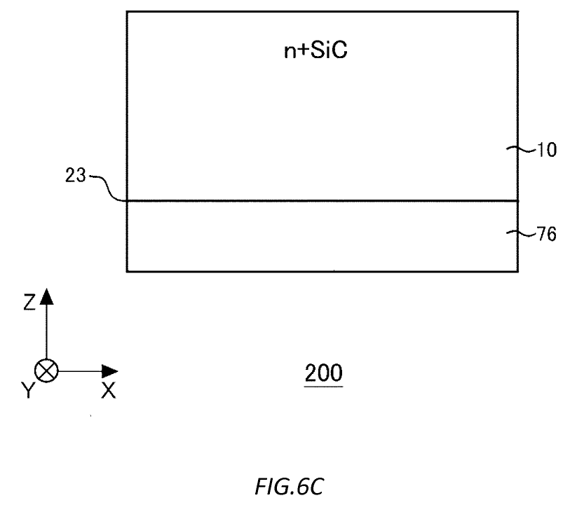

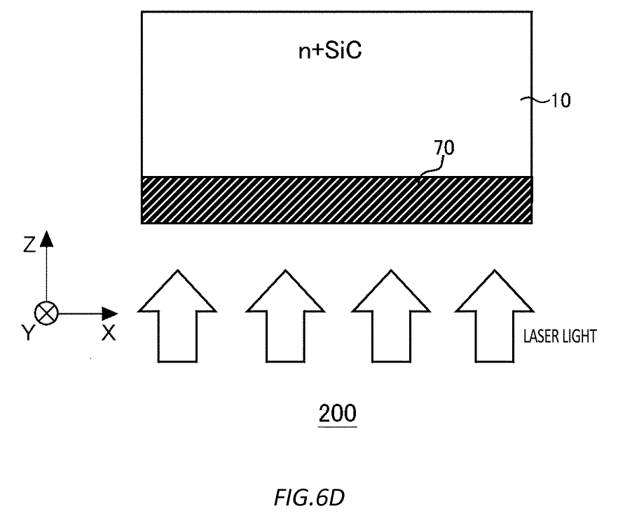

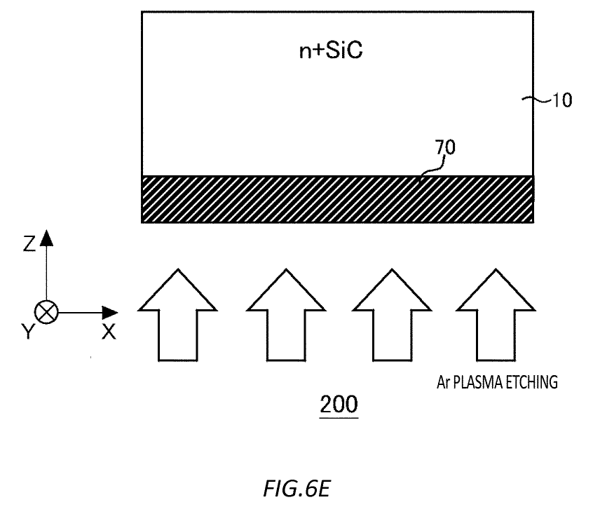

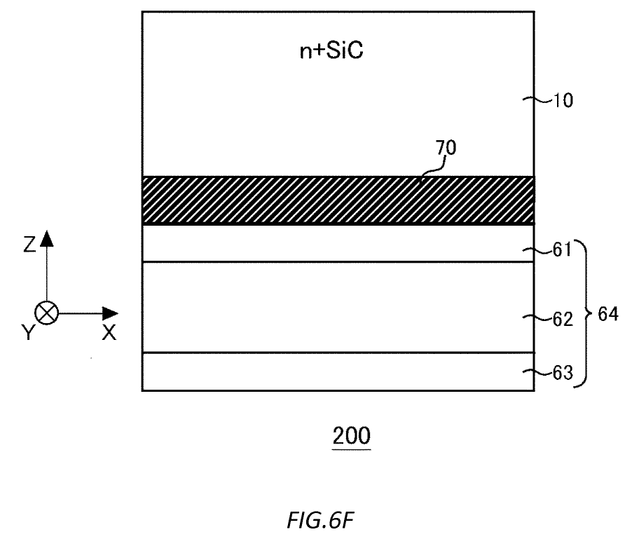

FIGS. 6A to 6F respectively show cross-sectional views of the semiconductor device 200 at manufacturing steps shown in FIG. 5. Note that in FIGS. 6A to 6F, the configuration on the upper surface 21 side from the silicon carbide substrate layer 10 is omitted. Description overlapping FIGS. 4A to 4G will be omitted as appropriate.

FIG. 6A shows a cross-sectional view of the semiconductor device 200 in the upper surface device structure forming step S1000. The upper surface device structure forming step S 1000 of the comparative example is similar to the upper surface device structure forming step S 1000 of the semiconductor device 100.

FIG. 6B shows a cross-sectional view of the semiconductor device 200 in the wafer thinning processing step S1002. In the comparative example, the crushed layer 82 is completely removed from the lower surface 23, which is a difference from the wafer thinning processing step S1002 of the semiconductor device 100.

FIG. 6C shows a cross-sectional view of the semiconductor device 200 in the ohmic metal deposition step S1004. In the comparative example, the ohmic metal 76 is deposited over the entire surface of the lower surface 23.

FIG. 6D shows a cross-sectional view of the semiconductor device 200 in the laser annealing step S1006. In the comparative example, the laser annealing is performed without causing the ohmic metal 76 to be agglomerated. Therefore, the metal silicide portion 70 is formed over the entire surface of the lower surface 23. In addition, even under the assumption that the ohmic metal 76 is agglomerated and the exposed region 34 is formed, the crushed layer 82 is removed, and thus the 3C-SiC crystal structure is not formed in the exposed region 34.

FIG. 6E shows a cross-sectional view of the semiconductor device 200 in the surface etching step S1008. In the surface etching step S1008, carbon precipitated at the surface of the metal silicide portion 70 in the laser annealing step S1006 is etched and removed.

FIG. 6F shows a cross-sectional view of the semiconductor device 200 in the lower surface electrode forming step S1012. In the lower surface electrode forming step S1012, the lower surface electrode 64 similar to that of the semiconductor device 100 is formed.

In the semiconductor device 200 of the comparative example, the metal silicide portion 70 is formed over the entire surface of the lower surface 23. In other words, the structure 1 in the semiconductor device 100 is formed over the entire surface of the lower surface 23. Therefore, adhesion is low, and there is a risk of delamination. In contrast to that, in a case of the present application, it is possible to form both of the structure 1 and the structure 2, and it is possible to form a contact with low resistance and with high contact reliability.

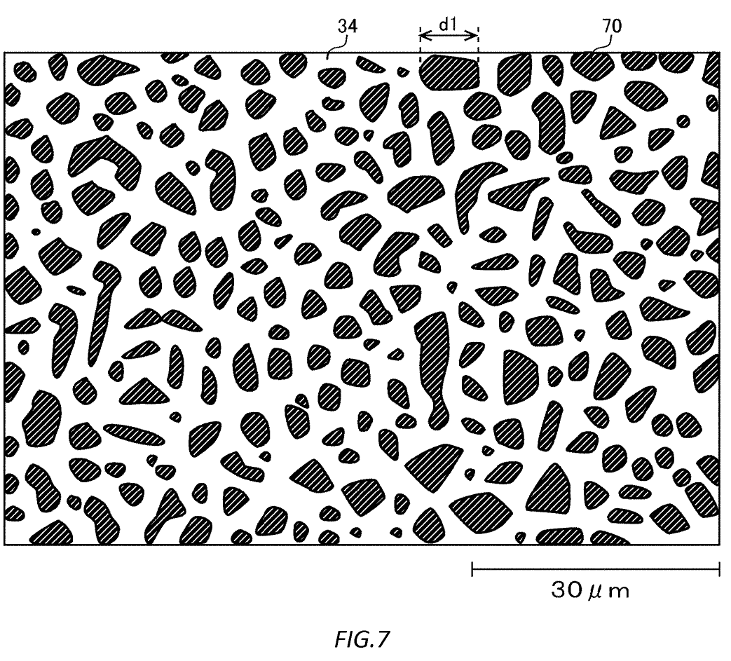

FIG. 7 shows an example of a schematic diagram of the lower surface 23 of the SiC substrate 11. FIG. 7 shows, in a bottom view, the metal silicide portion 70 and the exposed region 34 which are formed at the lower surface 23. The exposed region 34 of the present example surrounds the metal silicide portion 70 in the bottom view. In the first laser annealing step S1006, the ohmic metal 76 is agglomerated, thereby making it possible to form the configuration as shown in FIG. 7.

In FIG. 7, the metal silicide portion 70 is formed in a mottled pattern. Therefore, it is possible to finely arrange the exposed region 34 which has no risk of delamination, and it is possible to suppress a risk of delamination. Note that the exposed region 34 may be formed in a lattice pattern.

A length d1 of the metal silicide portion 70 in the bottom view may be 10 μm or less. As the metal silicide portion 70 is finely arranged, it is also possible to finely arrange the exposed region 34 which has no risk of delamination, and it is possible to suppress a risk of delamination. The length d1 may be an average value or a maximum value of the length of the metal silicide portion 70 in a predetermined region of the lower surface 23, or may be an average value or a maximum value of the length of the metal silicide portion 70 over the entire surface of the lower surface 23. The length d1 may be 5 μm or less, may be 1 μm or less, or may be 0.1 μm or less. The length d1 may be 0.01 μm or more. The metal silicide portion 70 and the exposed region 34 may coexist in a region having a diameter of 100 nm.

In the bottom view, an area of the exposed region 34 may be greater than an area of the metal silicide portion 70. The area of the exposed region 34 is a total area of portions of the exposed region 34 which overlap the lower surface electrode 64. The area of the metal silicide portion 70 is a total area of portions of the metal silicide portion 70 which overlap the lower surface electrode 64. By increasing the area of the exposed region 34 which has a reduced risk of delamination, it is possible to suppress a risk of delamination. The area of the exposed region 34 may be 1.2 times or more, may be 1.6 times or more, may be two times or more, or may be five times or more of the area of the metal silicide portion 70. The area of the exposed region 34 may be ten times or less of the area of the metal silicide portion 70.

In the bottom view, the area of the metal silicide portion 70 may be greater than the area of the exposed region 34. The area of the metal silicide portion 70 may be 1.2 times or more, may be 1.6 times or more, may be two times or more, or may be five times or more of the area of the exposed region 34. The area of the metal silicide portion 70 may be ten times or less of the area of the exposed region 34.

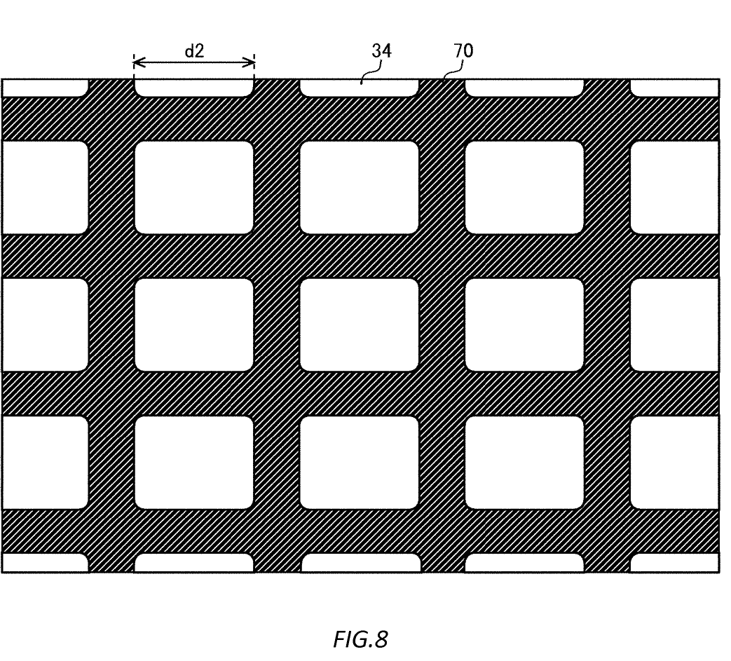

FIG. 8 shows another example of the schematic diagram of the lower surface 23 of the SiC substrate 11. The metal silicide portion 70 may surround the exposed region 34 in the bottom view. The metal silicide portion 70 of the present example is provided in a lattice pattern, and surrounds the exposed region 34. In the ohmic metal deposition step S1004 described above, by patterning the ohmic metal 76 to be deposited, it is possible to achieve the configuration shown in FIG. 8.

A length d2 of the exposed region 34 in the bottom view may be 10 μm or less. The length d2 may be an average value or a maximum value of the length of the exposed region 34 in a predetermined region of the lower surface 23, or may be an average value or a maximum value of the length of the exposed region 34 over the entire surface of the lower surface 23. The length d2 may be 5 μm or less, may be 1 μm or less, or may be 0.1 μm or less. The length d2 may be 0.01 μm or more. The metal silicide portion 70 and the exposed region 34 may coexist in a region having a diameter of 100 nm.

In the present example as well, in the bottom view, the area of the exposed region 34 may be greater than the area of the metal silicide portion 70. By increasing the area of the exposed region 34 in which there is no risk of delamination, it is possible to suppress a risk of delamination. The area of the exposed region 34 may be 1.2 times or more, may be 1.6 times or more, may be two times or more, or may be five times or more of the area of the metal silicide portion 70. The area of the exposed region 34 may be ten times or less of the area of the metal silicide portion 70.

In the bottom view, the area of the metal silicide portion 70 may be greater than the area of the exposed region 34. The area of the metal silicide portion 70 may be 1.2 times or more, may be 1.6 times or more, may be two times or more, or may be five times or more of the area of the exposed region 34. The area of the metal silicide portion 70 may be ten times or less of the area of the exposed region 34.

While the embodiments of the present invention have been described, the technical scope of the present invention is not limited to the above-described embodiments. It is apparent to persons skilled in the art that various alterations or improvements can be added to the above-described embodiments. It is also apparent from the described scope of the claims that the embodiments to which such alterations or improvements are added can be included in the technical scope of the present invention.

Note that the operations, procedures, steps, stages, or the like of each process performed by a device, system, program, and method shown in the claims, embodiments, or diagrams can be performed in any order as long as the order is not indicated by "prior to," "before," or the like and as long as the output from a previous process is not used in a later process. Even if the process flow is described using phrases such as "first" or "next" in the claims, embodiments, or diagrams, it does not necessarily mean that the process must be performed in this order.

What is claimed is:

1. A semiconductor device comprising:
a SiC substrate which has an upper surface and a lower surface;
an element structure which is formed on the upper surface of the SiC substrate;
a metal silicide portion which is formed at a part of the lower surface of the SiC substrate; and
a lower surface electrode which is in contact with the metal silicide portion and with an exposed region of the lower surface which is not covered by the metal silicide portion, wherein
at least a part of the exposed region has a crystal structure different from that of a contact region of the SiC substrate which is in contact with the metal silicide portion.

2. The semiconductor device according to claim 1, wherein
a crystal structure of the exposed region includes a 3C-SiC crystal structure.

3. The semiconductor device according to claim 2, wherein
a crystal structure of the contact region includes a 4H-SiC crystal structure.

4. The semiconductor device according to claim 1, wherein
the metal silicide portion is Ni silicide.

5. The semiconductor device according to claim 1, wherein
the lower surface electrode includes a Ti layer which is in contact with the exposed region.

6. The semiconductor device according to claim 5, wherein
the lower surface electrode has a stacked structure of the Ti layer, a Ni layer, and an Au layer from a lower surface side of the SiC substrate.

7. The semiconductor device according to claim 1, wherein
the exposed region surrounds the metal silicide portion in a bottom view.

8. The semiconductor device according to claim 7, wherein
a length of the metal silicide portion is 10 μm or less.

9. The semiconductor device according to claim 1, wherein
the metal silicide portion surrounds the exposed region in a bottom view.

10. The semiconductor device according to claim 1, wherein
in a bottom view, an area of the exposed region is greater than an area of the metal silicide portion.

11. The semiconductor device according to claim 1, wherein
in a bottom view, an area of the metal silicide portion is greater than an area of the exposed region.

12. The semiconductor device according to claim 2, wherein
in a depth direction of the SiC substrate, a thickness of a region having only the 3C-SiC crystal structure, is smaller than a thickness of a part of the metal silicide portion which is inside the SiC substrate.

13. A method for manufacturing a semiconductor device comprising:
depositing ohmic metal at least at a part of a lower surface of a SiC substrate;
performing laser annealing on the ohmic metal to cause agglomeration and silicidation, and forming a metal silicide portion;
performing laser annealing on at least a part of the lower surface of the SiC substrate to form a 3C-SiC crystal structure; and
forming a lower surface electrode to be in contact with both of the metal silicide portion and the 3C-SiC crystal structure.

14. The method for manufacturing a semiconductor device according to claim 13, wherein
a laser output in the laser annealing is higher when the ohmic metal is caused to be silicided, than a laser output in the laser annealing when the ohmic metal is caused to be agglomerated.

15. The semiconductor device according to claim 2, wherein
the lower surface electrode includes a Ti layer which is in contact with the exposed region.

16. The semiconductor device according to claim 3, wherein
the lower surface electrode includes a Ti layer which is in contact with the exposed region.

17. The semiconductor device according to claim 4, wherein
the lower surface electrode includes a Ti layer which is in contact with the exposed region.

18. The semiconductor device according to claim 2, wherein
the exposed region surrounds the metal silicide portion in a bottom view.

19. The semiconductor device according to claim 3, wherein
the exposed region surrounds the metal silicide portion in a bottom view.

20. The semiconductor device according to claim 4, wherein
the exposed region surrounds the metal silicide portion in a bottom view.
